(19) United States
(12) Patent Application Publication
(10) Pub. No.: US 2026/0237713 A1
(43) Pub. Date: Aug. 13, 2026

(54) TRANSPORT UNIT AND METHOD FOR PROVIDING A BATTERY MATERIAL FOR BATTERY MANUFACTURE, MANUFACTURING UNIT, AND MANUFACTURING SYSTEM

(71) Applicant: FRAUNHOFER-GESELLSCHAFT ZUR FÖRDERUNG DER ANGEWANDTEN FORSCHUNG EINGETRAGENER VEREIN, München (DE)

(72) Inventors: Marius HELLER, Münster (DE); Oliver KRÄTZIG, Münster (DE)

(21) Appl. No.: 19/160,403

(22) PCT Filed: Mar. 1, 2024
(86) PCT No.: PCT/DE2024/100169

§ 371 Date: Aug. 27, 2025

(30) Foreign Application Priority Data
Mar. 3, 2023 (DE) 10 2023 105 346.9

(51) Int. Cl. H01M 10/04

(52) U.S. Cl. CPC H01M 10/0404

(57) ABSTRACT

The invention relates to a transport unit (100, 100′, 120) for supplying a battery material (102, 102′, 122) for battery manufacturing, comprising a fluid-tight closable housing (104, 124), an interior chamber (106, 134) configured within the housing (104, 124) for arranging the battery material (102, 102′, 122), a handling interface (108, 136) for loading and unloading the interior chamber (106, 134) with battery material (102, 102′, 122), wherein the handling interface (108, 136) is arranged and configured to couple the transport unit (100, 100′, 120) to a production unit configured for battery production in such a way that a battery material (102, 102′, 122) arranged within the interior chamber (106, 134) can be removed independently of an atmosphere surrounding the transport unit (100, 100′, 120) in order to supply it to the production unit.

The invention relates to a transport unit and a method for supplying a battery material for battery production, a production unit for processing a battery material, and a production system for producing batteries and/or semi-finished battery products.

Transport units for the supply of a battery material for battery production are known in principle. As a rule, the processing of battery material takes place within a clean and/or dry room, the atmosphere of which, in particular the air in the clean and/or dry room, has a predetermined cleanliness class on the one hand and a low humidity on the other. In particular, the low humidity is required when processing the battery material, for example an electrode material, in order to meet the high requirements for batteries, for example for the automotive industry.

The requirements with regard to residual moisture and the particles still contained in the clean and/or dry room are constantly increasing. The investment costs of such a way cleanrooms and drying rooms are high. Furthermore, these requirements cause high costs and a high technical effort to maintain the functionality of such a clean and/or dry room.

Battery production can be divided into electrode production, cell assembly and cell finalization. Electrode production comprises a dry and a wet mixing process in which various components are prepared into a paste, a so-called slurry. The paste is applied to current collector foils, then dried and compacted in a so-called calendering process. The coated, dried and compacted films are then cut to a specific film width and usually wound into a coil. Finally, the electrodes produced in this way are dried under vacuum.

Cell assembly comprises the assembly of the battery components, in particular the electrodes, into a functional battery cell. The assembly steps are designed depending on the cell format. The electrodes, in particular the anodes and cathodes, are placed in a housing together with other components such as separators and arrester tabs. The housing is then filled with an electrolyte and sealed. This is followed by the cell finalization process, in which the cell is charged and discharged. The functionality of the cell is also tested during cell finalization.

The quality of the battery cells produced is determined in particular by the production technology applied and by the atmosphere in electrode production and cell assembly. One requirement of battery cell production is a clean and dry production environment due to the sensitive cell materials to be processed. Two parameters of the production environment are cleanliness, in particular the absence of particles, and humidity. As the humidity values to be achieved are low, the dew point is usually specified, for example −20° C., −40° C. or −60° C. Oxygen and/or CO2 reduction may also be required.

Moisture ingress can lead to surface passivation and electrolyte decomposition, which generates toxic hydrofluoric acid that negatively affects the performance of the cell. In addition, this results in increased gas formation and degradation effects in the cell, and therefore safety risks for operation. Another aspect of producing high-quality battery cells is ensuring that electrode production and cell assembly are essentially contamination-free.

Moisture can enter battery cell production in various ways. In order to maintain the required dew point with the lowest possible energy consumption, moisture ingress should be prevented.

The greatest input of moisture is caused by people and represents a critical source of moisture for the process. People release water into the environment through their breathing, perspiration or moisture in their clothing. In particular, the local influence of moisture through exhalation in the product or process environment is a critical and uncontrollable factor. A further entry of moisture takes place at airlocks if a person and/or material transfer takes place through these.

JP6897654B2 discloses a transport box for individual, layered electrodes ordered to shield them from an atmosphere. The transport box has a device ordered to provide a higher air pressure in the interior chamber of the transport box than the atmospheric pressure by means of dry air, so that no air from the atmosphere surrounding of the transport box enters the transport box. One of the disadvantages of this transport box is that it can be contaminated from the outside and this contamination and/or adhering moisture is introduced into the battery cell production.

DE 10 2021 004 571 A 1 discloses a method for cleaning exhaust air generated during a machining process in a clean room or drying room as well as a system for carrying out the method. However, contamination is not prevented when semi-finished products and/or personnel are transferred in and out.

CN112193597A discloses a transport box for batteries with a protective housing. This transport box also does not enable the contamination-free and/or moisture-free transfer of batteries within a battery cell production facility.

US2022140435A1 discloses a container for transporting and/or storing batteries, wherein openings are provided on a lid in order to flush gas under high pressure into the storage space of the container. This container also has the disadvantage that battery cell production would be contaminated by the introduction of the transport container.

There is a demand in the industry for high-purity battery cell production that can take place independently of the moisture and contamination of an atmosphere surrounding the battery cell production. In particular, the expected further increase in requirements for the dew point or the absence of contamination of the air within battery cell production means that concepts are required which go beyond the use of a previous clean and/or dry room.

It is therefore an object of the present invention to supply a transport unit, a production unit, a production system and a method which reduce or eliminate one or more of the aforementioned disadvantages. In particular, it is an object of the invention to supply a solution that enables improved battery cell manufacturing. Furthermore, it is an object of the invention to supply a solution that enables a more stable battery manufacturing process at a lower cost.

This problem is solved with a transport unit, a manufacturing unit, a manufacturing system and a method according to the features of the independent patent claims. Further advantageous embodiments of these aspects are given in the respective dependent patent claims. The features disclosed in the patent claims, the description and the drawings can be combined individually with one another in any technologically expedient manner, with further embodiments of the invention being shown.

According to a first aspect, the problem mentioned at the beginning is solved by a transport unit for the supply of a battery material for battery production, comprising a housing which can be closed in a fluid-tight manner, an interior chamber configured inside the housing for arranging the battery material, a handling interface for loading and unloading the interior chamber with battery material, wherein the handling interface is arranged and configured to couple the transport unit to a production unit configured for battery production in such a way that a battery material arranged within the interior chamber can be removed independently of an atmosphere surrounding the transport unit in order to supply it to the production unit.

The invention is based on the finding that battery cell production arranged exclusively within a clean and/or dry room does not meet the current and, in particular, future requirements with regard to dew point and purity, or only to a limited extent. For this reason, production units are further decoupled atmospherically from the clean and/or dry room so that optimized conditions prevail within the production unit compared to the clean and/or dry room in order to ensure a specified material quality. Such a way of atmospherically decoupled production units are also referred to as mini and/or micro environments. The atmospheric difference between the production unit and the clean and/or dry room must be taken into account when transferring the battery material to the production units within battery cell production.

The transport unit addresses these requirements, namely this transport unit can be used to transport the battery material into the clean and/or dry room and also within the clean and/or dry room between different production units and supply the individual production units contamination-free and independent of the humidity within the clean and/or dry room. This means that the battery material can be transported independently of the atmosphere of the clean and/or dry room and then processed within the production unit. The remarks on clean and/or dry rooms apply analogously to clean and/or gray rooms, which are comprised in particular by the terms clean and/or dry room.

The transport unit is configured for the supply of battery material for battery production. Supply is preferably also understood to mean storage and intermediate buffering. The battery material can be a semi-finished product, for example. The battery material can also be electrode foils, solid electrolytes, substrate foils, separators, intermediate products, preferably intermediate products that are transported in batches in magazines, for example, or housing elements. In particular, the transport unit is configured in such a way that it can be moved within a clean and/or drying room. Furthermore, the transport unit is preferably configured to be moved within the clean and/or dry room to one, two or more production units. Furthermore, the transport unit is configured in particular such that the battery material can be arranged within the interior chamber, taking into account that the battery material is supplied in the form of large-volume coils.

The transport unit comprises the fluid-tight sealable housing. A fluid-tight sealable housing means, in particular, that an atmosphere can be formed within the housing which is essentially unaffected by an atmosphere surrounding the transport unit. Fluid-tight can also mean particle-tight.

The interior chamber is configured within the housing. The housing preferably encloses the interior chamber, in particular in sections. The interior chamber is configured for arranging the battery material.

The transport unit also comprises the handling interface for loading and unloading the interior chamber with battery material. Preferably, the housing has the handling interface. It is preferred that the handling interface is the only opening in the housing. Alternatively, the housing can also have other openings that can be closed.

The handling interface is provided for loading and unloading the interior chamber with battery material. The handling interface preferably has a closable opening through which the battery material can be moved. The handling interface preferably has an openable closing element, for example a gate. The openable closing element is preferably arranged and configured in such a way that it can be opened and/or closed vertically and/or horizontally. The openable closing element can, for example, be configured so that it can be rolled up. The openable closing element preferably has a hydrophobic surface. The handling interface preferably has a roller unit which is arranged and configured to roll up and/or unroll the roll-up closing element. The roller unit preferably has a drive.

Furthermore, the handling interface is arranged and configured to couple the transport unit with a production unit designed for battery production. This coupling takes place in such a way that a battery material arranged within the interior chamber can be removed independently of an atmosphere surrounding the transport unit in order to supply it to the production unit. The fact that the battery material can be removed preferably also means that the battery material can be moved into the interior chamber independently of an atmosphere surrounding the transport unit. Preferably, the handling interface comprises coupling means with which the transport unit can be coupled to a closable opening of a production unit, for example an airlock. Opening units on production units in such a way are known to the person skilled in the art.

In particular, the handling interface is arranged and configured in such a way that the battery material is accessible after coupling with a production unit so that it can be moved out of the transport unit. In the following, different technical design variants are shown, with which handling of the battery material from the transport unit is possible.

A preferred embodiment of the transport unit is characterized by the fact that the handling interface is formed by a detachable housing element, and the detachable housing element is arranged and configured in such a way that it can be removed from the transport unit after coupling with the production unit. Furthermore, the handling interface can be the detachable housing element.

The detachable housing element can be a complete side of the housing or a side section of the housing. The side or this side section can be aligned horizontally or vertically or at an angle during intended operation. Removing the detachable housing element can mean removing or moving the detachable housing element. Displacement can be, for example, folding, pivoting or collapsing.

In a further preferred embodiment of the transport unit, it is provided that the handling interface is configured in such a way that the housing can be connected to the production unit in a fluid-tight manner after removal of the detachable housing element. Alternatively or additionally, the connection between the housing and the production unit can also be made before the detachable housing element is removed.

For example, the housing that does not have the detachable housing element can be arranged on the production unit with a sealing element. It is particularly preferred that the sealing element is arranged in such a way that the connection between the housing and the production unit is independent of the detachable housing element, so that the latter can be removed without affecting an atmosphere inside the housing and/or the production unit. The sealing element is preferably configured to be inflatable. The sealing element can be configured as a flat seal. The sealing element can have a cross-section of more than 5 mm.

A further preferred embodiment of the transport unit is characterized by the fact that the detachable housing element forms a base, a cover and/or a side of the housing.

A housing element forming the base has the advantage that the transport unit can be arranged vertically above the production unit, so that a contact pressure between the transport unit and the production unit is created gravitationally. This makes it advantageously possible to create a seal between the transport unit and the production unit.

A detachable housing element configured as a side of the housing has the advantage that the transport unit can be moved to the intended position of the production unit with little effort, for example by placing it to the side next to the production unit. In this case, it is preferable for the transport unit to be pulled and/or pressed against the production unit using pressure elements.

A similar advantage is achieved if the detachable housing element forms a cover for the housing. The fact that the detachable housing element forms a base, a lid and/or a side of the housing means in particular that it forms part of the base, the lid and/or the side of the housing. A pre-tensioning force and a pre-direction of the detachable housing element can be provided by peripheral units or by the drive unit.

It is preferred that the detachable housing element comprises, on a side facing away from the interior chamber, a sealing unit which is arranged and configured to interact with a manufacturing system, in particular a removal element of a manufacturing system. Furthermore, it is preferred that the transport unit has a movable, in particular hinged, cover element which is arranged and configured to cover the sealing unit in order to protect the sealing unit from contamination. The cover element is preferably arranged and configured in such a way that it exposes the sealing unit before the transport unit is coupled to a manufacturing system, so that the latter can interact with the manufacturing system, in particular the removal element.

The transport unit preferably comprises at least one sealing element which is arranged and configured to connect the detachable housing element to the housing in a substantially fluid-tight manner. It is preferred that the at least one sealing element is arranged outside the atmosphere configured for the battery material. Preferably, the sealing element is arranged on an outer wall of the housing. Alternatively, the sealing element can be arranged on the detachable housing element. Furthermore, it may be preferred that the sealing element is arranged inside the detachable housing element.

A further preferred embodiment of the transport unit comprises a second housing which is detachably arranged within the housing, wherein the second housing is fluidically separated from the housing, wherein preferably the housing is arranged and configured to be particle-tight and the second housing is fluid-tight.

The fact that the second housing is fluidically separated from the housing means in particular that an atmosphere different from the housing prevails in the second housing, for example a third atmosphere. The fact that the second housing is detachably arranged within the housing means, in particular, that the second housing can be removed from the housing and/or moved into the housing during intended operation.

The second housing has the advantage that the battery material is more decoupled from the environment of the transport unit. In particular, the housing and the second housing can provide different functions. Furthermore, loading and unloading can be made more contamination-free, for example by using air locks.

In a further preferred embodiment of the transport unit, it is provided that the second housing is firmly arranged within the housing.

An intermediate chamber is preferably configured between the second housing and the housing. The transport unit is preferably configured in such a way that a controlled atmosphere can be formed in the intermediate chamber. This controlled atmosphere is configured in particular with an inert gas, for example nitrogen and/or argon. The second atmosphere preferably has an overpressure relative to the ambient atmosphere, so that essentially no particles and/or moist air can or can penetrate into the intermediate chamber.

The intermediate chamber preferably has a smaller volume than the interior chamber. Preferably, the volume of the intermediate chamber is several times smaller than the volume of the interior chamber. The atmosphere to be controlled within the intermediate chamber can thus have a small volume, which reduces the media requirement. A targeted overflow from the intermediate chamber into the interior chamber can be achieved. It is preferred that there is a vacuum in the interior chamber and an overpressure in the intermediate chamber, in particular with an inert gas, for example nitrogen and/or argon. Furthermore, an overpressure can be configured in the interior chamber and in the intermediate chamber, whereby the pressure in the interior chamber is preferably greater than the overpressure in the intermediate chamber.

The detachable housing element is preferably double-walled, so that it is also configured as an intermediate chamber. It is preferred that the intermediate chamber between the first housing and the second housing and the intermediate chamber of the detachable housing element are fluidically coupled to one another. It is further preferred that the first housing and/or the second housing and the detachable housing element have corresponding fluid channels, for example bores, which are arranged and configured to couple them fluidically to one another.

A further preferred embodiment of the transport unit comprises a holding device for holding the battery material within the interior chamber, wherein the holding device is connected to the detachable housing element and is removable with the housing element. The holding device can, for example, be configured as a suspension.

In a further preferred embodiment, it is provided that the holding device for holding the battery material is arranged with a first end on the housing, in particular an inner wall of the housing, and a second end forms a fixed and/or loose bearing with the detachable housing element, so that the battery material is held securely during the intended operation of the transport unit. When the detachable housing element is detached from the housing, the fixed and/or loose mounting is released.

Furthermore, it is preferred that the holding device is configured in such a way that the battery material can be provided automatically, in particular with a handling unit, for example a gantry crane unit and/or an articulated robotic arm. In addition, the holding device can be a manipulator of a handling unit.

If the holding device is connected to the detachable housing element, the advantage is that the battery material can be moved directly with the housing element into the production unit. This reduces the number of handling steps required, as the unit comprising or consisting of the holding device, housing element and battery material is moved.

In a further preferred embodiment of the transport unit, it is provided that this comprises a media supply unit which is arranged and configured to cause an overpressure, in particular in a micro-overpressure range, in the interior chamber, so that contamination particles and/or a moist fluid can be conveyed out of the interior chamber and/or contamination particles and/or a moist fluid can be kept away from the interior chamber. For this purpose, the media supply unit preferably comprises a particle chamber in which the contamination particles and/or the moist fluid and/or a fluid separated from the moist fluid are stored. It is preferred that the overpressure is created with an inert gas. Preferably, the media supply unit comprises a fluid container, in particular for inert gas, for example nitrogen and/or argon.

In a further preferred embodiment of the transport unit, it is provided that the fluid container has a refill interface which is arranged and configured in such a way that the fluid container can be refilled by means of the refill interface. In particular, the refill interface is configured in such a way that the fluid container can be refilled automatically. For example, the transport unit can be moved to a fluid refill nozzle, in particular by means of the drive unit, which interacts with the refill interface in such a way that the fluid container can be refilled with the fluid.

In a further preferred embodiment of the transport unit, it is provided that the media supply unit is alternatively or additionally arranged and configured to apply a fluid flow to the battery material arranged in the interior chamber in such a way that particles are removed from the battery material and to feed the fluid flow having particles to a filter so that the particles are separated. Alternatively or additionally, the filter or an additional filter can be configured to dry the fluid flow. The fluid flow influenced in such a way is preferably fed to the interior chamber. The filter or filters are preferably arranged in the particle chamber.

A further preferred embodiment of the transport unit comprises a drive unit, which is arranged and configured to move the transport unit and which has a fluid reservoir, and a coupling interface, which is arranged and configured to position the housing on the drive unit and/or to connect the fluid reservoir fluidically to the interior chamber. The coupling between the drive unit and the housing can be direct or indirect. Alternatively or additionally, the fluid reservoir may be comprised by the housing and/or fluidically coupled to the housing. The fluid reservoir is preferably arranged outside the interior chamber. Furthermore, the fluid reservoir is preferably arranged on an outer wall, in particular on a lateral outer wall, of the housing. The fluid reservoir can be configured cylindrically and/or prismatically.

The drive unit can be firmly or detachably configured with the transport unit. It is also preferred that the transport unit and the drive unit are configured and can be arranged in such a way that the drive unit can be moved under the transport unit and coupled to it.

The drive unit is configured to be rail- or vehicle-guided, for example.

A further preferred embodiment of the transport unit comprises a control device coupled by signals to the drive unit, which is adapted to receive a positioning command characterizing a position to be approached by the transport unit and to control the drive unit based on the positioning command. The drive unit is controlled based on the positioning command, in particular in such a way that the position to be approached is approached.

In a further preferred embodiment of the transport unit, it is provided that the transport unit comprises a movement device which is arranged and configured to move the battery material and/or the holding device out of the interior chamber and/or into the interior chamber. The movement device can, for example, be configured as a linear unit. The movement device may, for example, have rails on which the battery material and/or the holding device can be arranged in a movable manner. The movement device can preferably be actuated by means of a medium, in particular compressed air and/or electrical power. The medium is preferably supplied by the media supply unit.

Furthermore, the transport unit preferably comprises a media interface for coupling the transport unit to the production unit. The media interface is configured in particular to receive the medium. Preferably, the media interface is configured to receive compressed air of up to 10 bar. Furthermore, it is preferred that the media interface is arranged and configured in such a way that pressure equalization between the interior chamber and the production unit occurs after the transport unit is coupled to a production unit.

In a further preferred embodiment of the transport unit, it is provided that it has a fluid unit with a desiccant, which is arranged and configured to generate a dried fluid flow. The desiccant is arranged and configured to dry the fluid. The desiccant is or comprises preferably a water-binding material. The desiccant is or comprises, for example, silica gel and/or a molecular sieve. The desiccant is preferably incorporated in a replaceable drying module. The fluid from the fluid unit and/or the fluid reservoir is preferably supplied on demand. The fluid unit and/or the desiccant, in particular the desiccant module, is/are preferably arranged outside the interior chamber. Furthermore, it is preferred that the fluid unit and/or the desiccant, in particular the desiccant module, is or are arranged on an outer wall, in particular an upper outer wall.

In a further preferred embodiment of the transport box, it is provided that the transport box comprises at least one fluid flow guiding element which is arranged and configured to guide the fluid flow within the interior chamber according to a predefined flow pattern. In particular, it is preferred that the fluid flow is directed towards the detachable housing element in such a way that contamination during removal of the housing element is avoided or reduced. Furthermore, it is preferred that the fluid flow is directed in such a way that an air wall is configured adjacent to the detachable housing element. Furthermore, air slots can be provided to form an air curtain.

A preferred embodiment of the transport unit comprises a dew point sensor and/or a pressure sensor, which are arranged and configured to measure the dew point and/or the pressure in the interior chamber.

According to a further aspect, the problem mentioned at the beginning is solved by a production unit for processing a battery material, comprising a removal unit for removing a detachable housing element, a transport unit, in particular a transport unit according to one of the embodiments described above, so that a battery material arranged in the transport unit and/or on the housing element can be removed, and/or a handling unit which is arranged and configured to remove the battery material.

The manufacturing unit can be configured for processing and/or storing the battery material. The production unit preferably comprises a production room and/or storage room in which the battery material can be processed and/or stored. The production room and/or storage room is preferably configured to be fluid-tight with respect to an environment of the production unit.

Removing the detachable housing element from the transport unit means, in particular, driving or moving the housing element away from the transport unit. In the transport unit means, in particular, in an interior chamber of a housing of the transport unit.

The removal unit is preferably configured for translational movement of the housing element. In particular, the removal unit is configured for vertical translational movement of the housing element. The handling unit can be, for example, a gantry crane unit and/or an articulated robotic arm and/or a linear unit. Furthermore, it may be preferred that the handling unit can be moved in translation, so that it can be moved, for example, by an airlock unit described below. Furthermore, a handling unit that can be moved in translation can serve several production lines, so that only one interface is required for several production lines. The handling unit is preferably configured to move the battery material into the production room and/or storage room.

In a preferred embodiment of the manufacturing unit, it is provided that the removal unit has a removal element corresponding to the detachable housing element, in particular to an outer side of the detachable housing element, for coupling with the detachable housing element. A removal element of such a way minimizes contamination by the housing of the transport unit. This is achieved in particular by the fact that a large part of the contaminated surface of the housing element is covered by the removal element.

In a further preferred embodiment of the manufacturing unit, it is provided that the removal unit for coupling with the detachable housing element is arranged and configured in such a way that contaminated surfaces of the housing element are covered. The removal unit may, for example, have sleeves, in particular rubber sleeves, into which the housing element can be inserted in sections so that contaminated surfaces of the housing element do not contaminate the production unit. Contaminated surfaces are to be understood in particular as those surfaces that are directed outwards during the intended operation of the transport unit and thus come into contact with the atmosphere surrounding the production unit, for example a clean and/or dry room. An outward-facing surface of the production unit or the airlock unit can also be a contaminated surface.

The transport unit and/or the production unit preferably have a coupling in order to connect them to each other. The coupling is further preferably configured mechanically. Mechanical couplings comprise in particular physical connections such as screws, bolts or springs. Further preferably, the coupling is configured magnetically. Magnetic couplings have magnets in order to connect the transport unit to the production unit without contamination. The coupling can also be configured pneumatically and/or electrically. Pneumatic couplings are arranged and configured to supply compressed air in such a way that the transport unit can be connected to the production unit without contamination.

The coupling can also be configured as a flange coupling. Flange couplings use flanges in order to connect the transport unit to the production unit without contamination. Furthermore, the coupling can be designed as a quick coupling. Quick couplings comprise locking elements in order to connect the transport unit to the production unit without contamination.

In a further preferred embodiment of the manufacturing unit, it is provided that the removal unit with the detachable housing element is arranged to be movable from a coupling position, in which the removal unit can be coupled to the detachable housing element, to a transfer position, in which the battery material can be removed with the handling unit. For example, the coupling position can be vertically spaced from the transfer position. Preferably, the coupling position is vertically above the transfer position.

In a further preferred embodiment of the manufacturing unit, this comprises an airlock unit with an airlock chamber which has a first closable side and a second closable side, wherein the transport unit can be coupled to the manufacturing unit at the first closable side and the second closable side is adjacent to a manufacturing chamber and wherein an atmosphere of the airlock chamber can be adjusted with a fluid device.

The airlock unit preferably comprises a fluid overflow unit which is arranged and configured to build up a fluid barrier in order to avoid or reduce contamination. The fluid barrier can be, for example, an air barrier or an air sword.

According to a further aspect, the problem mentioned at the beginning is solved by a manufacturing system for producing batteries and/or battery semi-finished products, comprising a manufacturing unit according to one of the embodiments described in the preceding embodiment and/or a transport unit according to one of the embodiments described in the preceding embodiment.

A manufacturing system of such a way has the advantage that battery manufacturing can take place in an environment that meets even higher Claims than battery manufacturing that takes place exclusively in a clean and/or dry room. Furthermore, the manufacturing system makes it possible that not all manufacturing units have to be located in a clean and/or dry room, so that the disadvantages of a clean and/or dry room described above are avoided or reduced.

In particular, it is preferred that the transport unit has the detachable housing element and the production unit has the removal unit for removing the detachable housing element, so that a coupling between the transport unit and the production unit for removing the battery material is advantageously possible. Preferably, the removal unit can be connected to the detachable housing element with a removal element so that the detachable housing element can be removed from the housing so that the battery material is accessible.

In a preferred embodiment of the manufacturing system, it is provided that the manufacturing unit is arranged within a clean and/or dry room and has a manufacturing chamber which is configured in such a way that a first atmosphere in the manufacturing chamber is independent of a second atmosphere of the clean and/or dry room, and the first atmosphere prevails in the interior chamber of the transport unit, so that the battery material can be moved from the transport unit to the manufacturing chamber by means of the handling interface without being influenced by the second atmosphere. In the second atmosphere of the clean and/or dry room, there may be people in the intended operation of the manufacturing system who introduce moisture and/or particles.

According to a further aspect, the problem mentioned at the beginning is solved by a method for supplying a battery material for battery production, comprising the steps of: arranging a battery material within a housing of a transport unit and sealing the housing in a fluid-tight manner, moving the transport unit to a manufacturing unit for processing the battery material, coupling the transport unit to the manufacturing unit in a fluid-tight manner by means of a handling interface and opening the handling interface so that the battery material is supplied to the manufacturing unit independently of an atmosphere surrounding the transport unit.

The battery material can be arranged within the housing during electrode production and/or cell assembly. For example, the arrangement takes place after the battery material has been pre-processed, in particular into a coil. The battery material was preferably pre-processed in a clean room and/or dry room atmosphere, whereby the last process step can be vacuum drying.

In a preferred embodiment of the method, it is provided that the handling interface is configured by a detachable housing element of the housing and the opening of the handling interface comprises the step: Removing the detachable housing element so that the battery material is accessible and can be supplied to the manufacturing unit. The removal is preferably carried out with a removal device comprising the step: moving the housing element into an interior chamber of the production unit. Preferably, the housing element is moved vertically.

For further advantages, embodiment variants and embodiment details of the individual aspects and their possible embodiments, reference is also made to the description given for the further aspects, the corresponding features and embodiments.

Preferred embodiments are explained by way of example with reference to the enclosed figures. They show

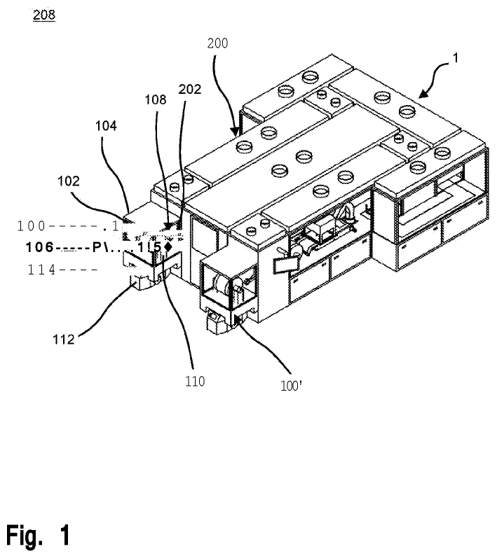

FIG. 1: a schematic, three-dimensional view of an exemplary embodiment of a manufacturing system;

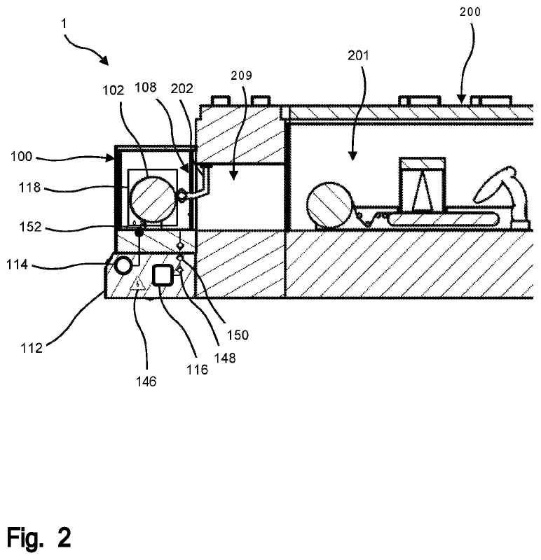

FIG. 2: a schematic, two-dimensional sectional view of the manufacturing system shown in FIG. 1;

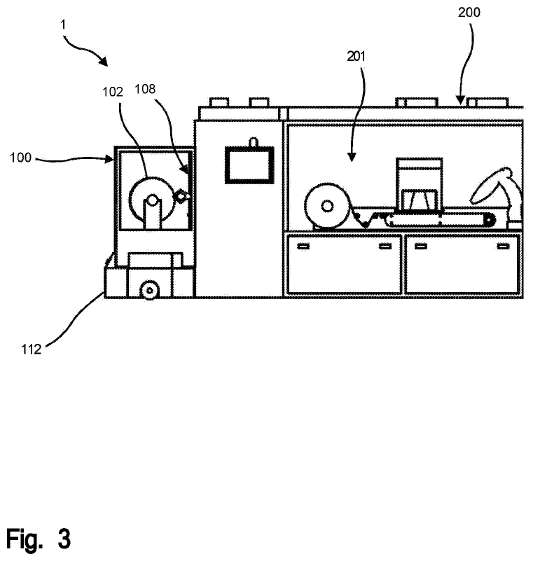

FIG. 3: a schematic, two-dimensional side view of the manufacturing system shown in FIG. 1;

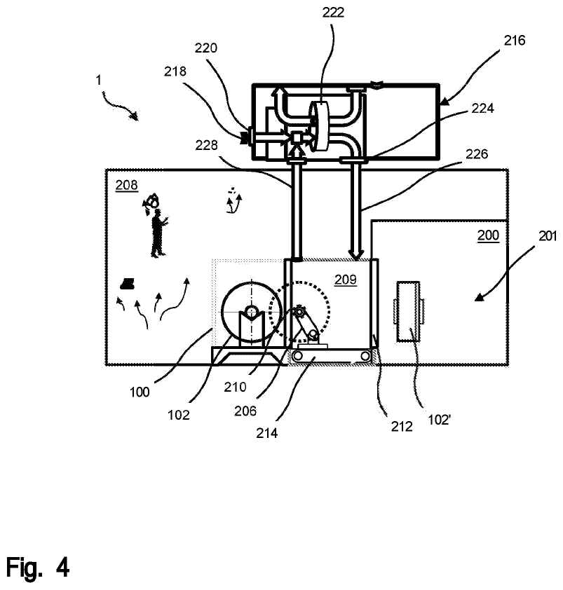

FIG. 4: a schematic, two-dimensional view of an exemplary embodiment of a manufacturing system;

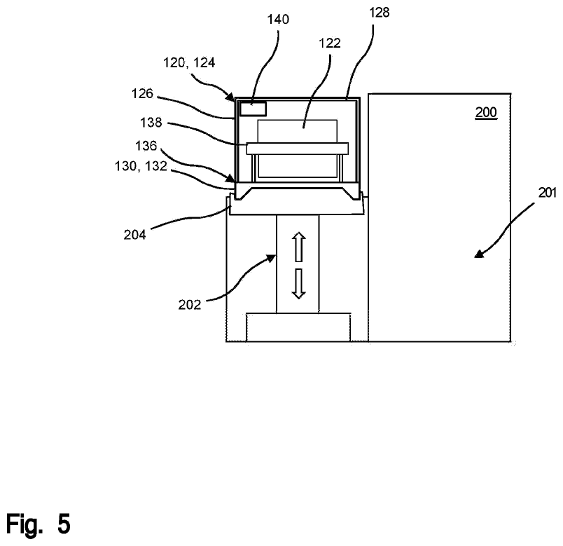

FIG. 5: a schematic, two-dimensional view of an exemplary embodiment of a manufacturing unit with a transport unit;

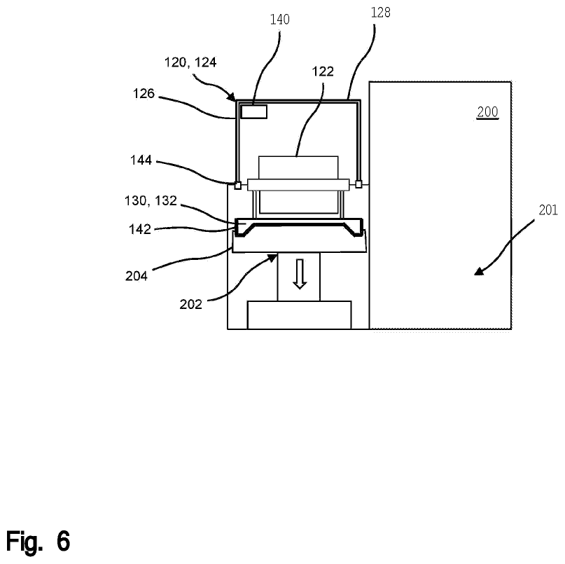

FIG. 6: a schematic, two-dimensional view of an exemplary embodiment of a manufacturing unit with a transport unit;

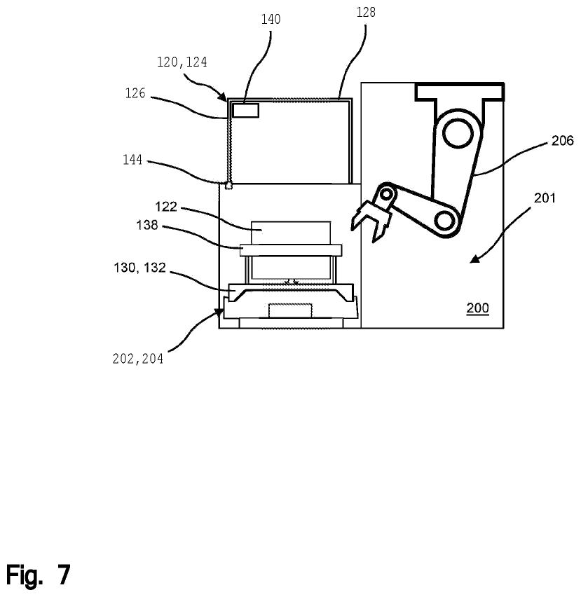

FIG. 7: a schematic, two-dimensional view of an exemplary embodiment of a manufacturing unit with a transport unit;

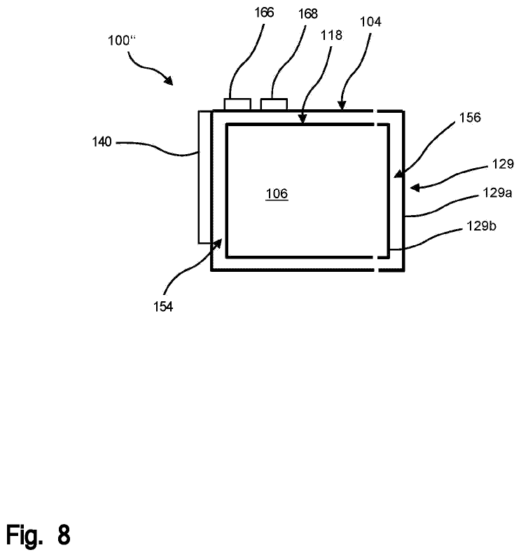

FIG. 8: a schematic, two-dimensional view of an exemplary embodiment of a transport unit;

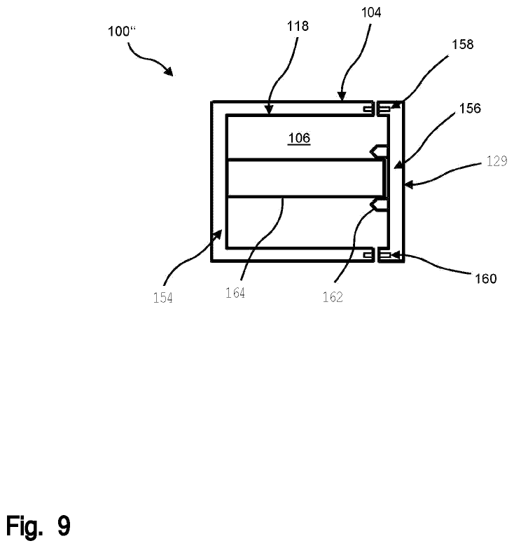

FIG. 9: a schematic, two-dimensional view of an exemplary embodiment of a transport unit;

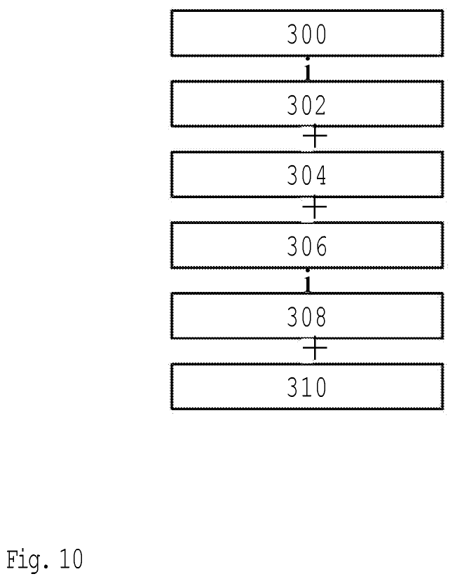

FIG. 10: a schematic view of an exemplary method.

In the figures, identical or essentially functionally identical or similar elements are designated with the same reference signs.

The embodiment examples explained below are ordered to preferred embodiments of the invention. In the embodiment examples, the described components of the embodiments each represent individual features of the invention which are to be considered independently of each other, which also further form the invention independently of each other and are thus also to be regarded as part of the invention individually or in a combination other than that shown. Furthermore, the embodiments described can also be supplemented by other features of the invention already described.

FIGS. 1, 2, and 3 show a manufacturing system 1 for producing batteries and/or semi-finished battery products. The manufacturing system 1 comprises a manufacturing unit 200 to which two transport units 100, 100′ are coupled. The manufacturing unit has the manufacturing space 201, in which a laser separation is shown as an example. The manufacturing system 1 is arranged within a clean and/or dry room 208. Alternatively, the manufacturing system 1 may be partially or completely arranged in an environment that is not a clean and/or dry room.

The transport unit 100 comprises a housing 104 that encloses an interior chamber 106. A battery material 102 is disposed within the interior chamber 106, which may be, for example, an electrode material. In figure two, a second housing 118 is shown as an example, which is detachably arranged within the housing 104. The second housing 118 is fluidically separated from the housing 104.

The transport unit 100 further comprises the handling interface 108. The handling interface 108 enables the housing 104 to be opened so that a removal unit 202 and/or a handling unit 206 can reach the transport unit 100. The removal unit 202 and/or the handling unit 206 can be configured as a pivotable robot system on a linear axis. The battery material 102 is arranged on a holding device 110.

In addition, the transport unit 100 comprises a drive unit 112, which can be configured as an AGV (Automated Guided Vehicle, also: driverless transport system). The housing 104 is arranged on the drive unit 112. Furthermore, the drive unit 112 comprises a control device 114 adapted to receive a positioning command characterizing a position to be approached by the transport unit 100 and to control the drive unit 102 based on the positioning command.

The transport unit 100 further comprises a media supply unit 116 which is arranged and configured to maintain an atmosphere, for example the first atmosphere, in the interior chamber 106. The media supply unit 116 may, for example, form an air blade and/or an air lock. For example, the media supply unit 116 can cause an overpressure in the interior chamber 106 so that contamination particles and/or a moist fluid can be conveyed out of the interior chamber 106. The transport unit 100′ has a similar structure. The media supply unit 116 is fluidically coupled to the interior chamber 106 by means of a valve 148 and a quick coupling unit 150. Furthermore, the media supply unit and/or the control device 114 is supplied with electrical power by means of a power supply unit 146. Parameters of the atmosphere in the interior chamber 106 can be determined by means of a sensor unit 152.

FIG. 4 shows a sectional drawing in which the coupling of the transport unit 100 to the manufacturing unit 200 is shown in detail. After the transport unit 100 is coupled to the production unit 200, the handling interface 108 can open. The battery material 102 can then be removed by means of the handling unit 206.

The handling unit 206 is arranged within an airlock unit with an airlock chamber 209. The airlock unit comprises a first lockable airlock 210 and a second lockable airlock 212. After the handling unit 206 has removed the battery material 102, the handling unit 206 is moved towards the second airlock 212 by the movement unit 214. The battery material 102 with handling unit 206 is then introduced into the production space 201 of the production unit 200. In the state shown, the battery material 102′ is arranged in the production space 201.

The airlock chamber 209 can be cleaned with a fluid device 216. For this purpose, the fluid device 216 comprises a fresh air inlet 218, a filter 220, a drying, inert gas and/or vacuum unit 222, a further filter 224, a fluid supply 226 and a fluid discharge 228. Thus, residual particles or residual moisture that have entered the airlock chamber 209 despite the handling interface 108 can be disposed of.

FIGS. 5 to 7 show an alternative variant in which the handling interface 136 has a detachable housing element 132 configured as a base element 130. Analogous to the transport unit 100 described above, the transport unit 120 has a housing 124, an interior chamber 134, a holding device 138 and a media supply unit 140.

The battery material 122 is held by the holding device 138. The housing 124 comprises four side walls 126, a lid 128 and a bottom element 130. The bottom element 130 is configured as the detachable housing element 132. In particular, the base element 130 is interchangeably arranged. Furthermore, the bottom element 130 may be configured to be modularly adaptable. The bottom element 130 can be configured in multiple parts so that contaminated surfaces can be kept away from the first atmosphere.

In intended operation, the transport unit 120 is arranged on the production unit 200. The removal unit 202 with the removal element 204 is then moved towards the base element 130, so that the removal unit 202 is in a coupling position. The base element 130 is decoupled from the rest of the housing 124 by a mechanism not shown, so that the base element 130 with the removal element 204 can be moved downwards in a vertical direction. This state is shown in particular in FIG. 6. The manufacturing unit 200 may be configured to be openable with a lock element not shown.

Furthermore, a sleeve 142 is shown in FIG. 6, which covers the contaminated surfaces of the housing element 132. Further, the housing 124 comprises seals 144 ordered to form a fluid-tight coupling with the manufacturing unit 200.

FIG. 7 shows the transfer position of the removal unit 202. The handling unit 206 can now be used to supply the battery material 122, optionally with the holding device 138 and the manufacturing unit 200 for further processing.

FIGS. 8 and 9 show further preferred embodiments of a transport unit 100″. In FIG. 8, it is shown that the transport unit 100″ comprises an outer housing 104 and an inner, second housing 118. A first intermediate chamber 154 is configured between the housings 104 and 118. The transport unit 100″ further comprises the detachable housing element 129, which has an outer housing element 129a and an inner housing element 129b. A second intermediate chamber 156 is configured between the outer housing element 129a and the inner housing element 129b. By means of the intermediate chambers 154, 156, it is possible to maintain a predefined atmosphere, whereby the volume for this predefined atmosphere is small compared to the interior chamber 106. Thus, the predefined atmosphere can be maintained more safely and with less effort. The predefined atmosphere is maintained and configured by, among other things, the prismatically configured media supply unit 140. Furthermore, the transport unit 100″ comprises a fluid unit 166 for forming a fluid flow and a drying means 168 for drying the fluid flow.

FIG. 9 shows that a mandrel 164 is arranged within the interior chamber 106. In a particularly preferred manner, a coil of battery material can be arranged on the mandrel 164. In order to enable particularly safe transportation of the coil of battery material, the mandrel 164 interacts with a mandrel bearing 162. The mandrel bearing 162 is arranged on the detachable housing element 129. Fluid channel couplings 158, 160 are arranged and configured to exchange fluid between the intermediate chambers 154, 156.

The method of FIG. 10 comprises six main steps. In step 300, the battery material 102, 102′, 122 is disposed within the housing 104, 124 of the transport unit 100, 100′, 120. In step 302, the housing 104, 124 is sealed in a fluid-tight manner.

In step 304, the transport unit 100, 100′, 120 is moved to a manufacturing unit 200 for processing the battery material 102, 102′, 122.

In step 306, the transport unit 100, 100′, 120 is coupled to the manufacturing unit 200 in a fluid-tight manner by means of the handling interface 108, 136.

In step 308, the handling interface 108, 136 is opened so that the battery material 102, 102′, 122 is supplied to the manufacturing unit 200 independently of an atmosphere surrounding the transport unit 100, 100′, 120. In step 310, the releasable housing element 132 is removed so that the battery material 102, 102′, 122 is accessible and can be supplied to the manufacturing unit 100.

The transport unit 100, 100′, 120, the manufacturing unit 200, the manufacturing system 1 and the method, as described above, enable higher quality and more energy efficient producing of batteries, as the battery material 102, 102′, 122 processed into the batteries has lower levels of contamination and is handled in an atmosphere with a lower dew point. Thus, generally higher quality batteries can be produced and waste and subsequent testing steps are reduced.

### REFERENCE SIGNS

1 Production system
100, 100′, 100″ Transport unit
102, 102′ Battery material
104 Housing
106 Interior chamber
108 Handling interface
110 Mounting device
112 Drive unit
114 Control device
116 Media supply unit
118 Second housing
120 Transport unit
122 Battery material
124 Housing
126 Side panel
128 Cover
129 Detachable housing element
129a outer housing element
129b inner housing element
130 Base element
132 Housing element
134 Interior chamber
136 Handling interface
138 Holding device
140 Media supply unit
142 Collar
144 Seal
146 Power supply unit
148 Valve
150 Quick coupling unit
152 Sensor unit
154 First intermediate chamber
156 Second intermediate chamber
158 First fluid channel coupling
160 Second fluid channel coupling
162 Mandrel bearing
164 Mandrel
166 Fluid unit
168 Desiccant
200 Production unit
201 Production area
202 Removal unit
204 Removal element
206 Handling unit
208 Clean and/or drying room
209 Airlock room
210 First airlock
212 Second airlock
214 Movement unit
216 Fluid device
218 Fresh air inlet
220 Filter
222 Drying, inert gas and/or vacuum unit
224 Filter
226 Fluid supply
228 Fluid discharge
300-310 Process steps

1. A transport unit (100, 100′, 120) for supply of a battery material (102, 102′, 122) for battery production, comprising
a housing (104, 124) which can be closed in a fluid-tight manner,
an interior chamber (106, 134) configured within the housing (104, 124) for arranging the battery material (102, 102′, 122),
a handling interface (108, 136) for loading and unloading the interior chamber (106, 134) with battery material (102, 102′, 122),
wherein the handling interface (108, 136) is arranged and configured to couple the transport unit (100, 100′, 120) to a production unit configured for battery production in such a way that a battery material (102, 102′, 122) arranged within the interior chamber (106, 134) can be removed independently of an atmosphere surrounding of the transport unit (100, 100′, 120) in order to supply it to the production unit.

2. The transport unit (100, 100′, 120) according to claim 1, wherein
the handling interface (108, 136) is configured by a detachable housing element (132), and
the detachable housing element (132) is arranged and configured in such a way that it can be removed from the transport unit (100, 100′, 120) after coupling with a manufacturing unit.

3. The transport unit (100, 100′, 120) according to claim 2, wherein
the handling interface (108, 136) is configured in such a way that, after removal of the detachable housing element (132), the housing (104, 124) can be connected to the manufacturing unit in a fluid-tight manner.

4. The transport unit (100, 100′, 120) according to claim 2, wherein
the detachable housing element (132) forms a base (130), a cover (128) and/or a side (126) of the housing (104, 124).

5. The transport unit (100, 100′, 120) according to claim 1, comprising
a second housing (118) which is detachably arranged within the housing (104, 124),
wherein the second housing (118) is fluidically separated from the housing (104, 124),
wherein the housing (104, 124) is configured to be particle-tight and the second housing (118) is configured to be fluid-tight.

6. The transport unit (100, 100′, 120) according to claim 2, comprising
a holding device (110, 138) for holding the battery material (102, 102′, 122) within the interior chamber (106, 134),
wherein the holding device (110, 138) is connected to the detachable housing element (132) and is removable with the detachable housing element (132).

7. The transport unit (100, 100′, 120) according to claim 1, comprising
a media supply unit (116, 140) arranged and configured to maintain an atmosphere in the interior chamber (106).

8. The transport unit (100, 100′, 120) according to claim 1, comprising
a drive unit (112) which is arranged and configured to move the transport unit (100, 100′, 120) and which has a fluid reservoir, and
a coupling interface which is arranged and configured to position the housing (104, 124) on the drive unit (112) and/or to fluidically connect the fluid reservoir to the interior chamber (106, 134).

9. The transport unit (100, 100′, 120) according to claim 8, comprising
a control device (114) coupled by signals to the drive unit (112), which is adapted to receive a positioning command wherein a position to be approached by the transport unit (100, 100′, 120) and to control the drive unit (112) based on the positioning command.

10. A manufacturing unit (200) for processing a battery material (102, 102′, 122), comprising
a removal unit (202) for removing a detachable housing element (132) of a transport unit (100, 100′, 120) according to claim 1, so that a battery material (102, 102′, 122) arranged in the transport unit (100, 100′, 120) and/or on the housing element (132) can be removed, wherein the battery material (102, 102′, 122) is arranged in the transport unit (100, 100′, 120) and/or on the housing element (132).
a handling unit (206) which is arranged and configured to remove the battery material (102, 102′, 122).

11. The manufacturing unit (200) according to claim 10, wherein the removal unit (202) has a removal element (204) corresponding to the detachable housing element (132) for coupling with the detachable housing element (132).

12. The manufacturing unit (200) according to claim 10, wherein
the removal unit (202) for coupling with the detachable housing element (132) is arranged and configured in such a way that contaminated surfaces of the housing element (132) are covered.

13. The manufacturing unit (200) according to claim 10, wherein
the removal unit (202) is arranged movably with the detachable housing element (132) from a coupling position, in which the removal unit (202) is couplable with the detachable housing element (132), to a transfer position, in which the battery material (102, 102′, 122) is removable with the handling unit (206).

14. The manufacturing unit (200) according to claim 10, comprising
an airlock unit with an airlock chamber (209) having a first closable side (210) and a second closable side (212),
wherein the transport unit (100, 100′, 120) can be coupled to the production unit at the first closable side and the second closable side is adjacent to a production space (201), and
wherein an atmosphere of the airlock chamber (209) is adjustable by of a fluid device (216).

15. A manufacturing system (1) for producing batteries and/or battery semi-finished products, comprising
a manufacturing unit (200) according to claim 10, and/or
a transport unit (100, 100′, 120).

16. The manufacturing system (1) according to claim 15, wherein
the manufacturing unit (200) is arranged within a clean and/or dry room (208) and has a manufacturing space (201) configured such a way that a first atmosphere in the manufacturing space (201) is independent of a second atmosphere of the clean and/or dry room (208), and
the first atmosphere prevails in the interior chamber (106, 134) of the transport unit (100, 100′, 120), so that the battery material (102, 102′, 122) can be moved from the transport unit (100, 100′, 120) to the manufacturing space (201) by the handling interface (108, 136) without being influenced by the second atmosphere.

17. A method for supplying a battery material (102, 102′, 122) for battery manufacturing, with a transport unit according to claim 1, comprising the steps of:
arranging a battery material (102, 102′, 122) within a housing (104, 124) of a transport unit (100, 100′, 120) and closing the housing (104, 124) in a fluid-tight manner,
moving the transport unit (100, 100′, 120) to a production unit for processing the battery material (102, 102′, 122),
fluid-tight coupling of the transport unit (100, 100′, 120) to the production unit by a handling interface (108, 136), and
opening the handling interface (108, 136) so that the battery material (102, 102′, 122) is supplied to a manufacturing unit independently of an atmosphere surrounding the transport unit (100, 100′, 120).

18. The method according to claim 17, wherein the handling interface (108, 136) is configured by a releasable housing element (132) of the housing (104, 124) and the opening of the handling interface (108, 136) comprises the step of:
removing the releasable housing element (132) so that the battery material (102, 102′, 122) is accessible and can be supplied to the manufacturing unit.
